(19) United States
(12) Patent Application Publication
(10) Pub. No.: US 2017/0204126 A1
(43) Pub. Date: Jul. 20, 2017

(54) MOLYBDENUM- AND TUNGSTEN-CONTAINING PRECURSORS FOR THIN FILM DEPOSITION

(71) Applicants: Christian DUSSARRAT, Houston, TX (US); Antoine COLAS, Houston, TX (US); Jong Min KIM, Houston, TX (US); L'Air Liquide, Société Anonyme pour l'Etude et l'Exploitation des Procédés Georges Claude, Paris (FR)

(72) Inventors: Christian DUSSARRAT, Tokyo (JP); Antoine COLAS, Ozoir la Ferriere (FR); Jong Min KIM, Tsukubamirai-shi (JP)

(21) Appl. No.: 15/324,335

(22) PCT Filed: Jul. 7, 2015
(86) PCT No.: PCT/JP2015/003422

§ 371 Date: Jan. 6, 2017

Related U.S. Application Data
(60) Provisional application No. 62/021,400, filed on Jul. 7, 2014.

(51) Int. Cl. C07F 11/00; H01L 51/00; C23C 18/12; H01L 51/52; C23C 16/40; C23C 16/455

(52) U.S. Cl. CPC C07F 11/005; C23C 16/405; C23C 16/45553; C23C 18/1216; C23C 18/125; H01L 51/5212; H01L 51/5228; H01L 51/0021; H01L 2251/303

(57) ABSTRACT

Electrochromic tungsten or molybdenum oxide and their doped derivative nanomaterials are prepared using sol-gel or vapor deposition methods from precursors containing only tungsten, oxygen, carbon and hydrogen, as other elements can generate optical defects impacting the electrochromic performances. Preferably, the liquid and volatile compound W(═O)(OsBu)₄ is the precursor used.

### CROSS REFERENCE TO RELATED APPLICATIONS

The present application claims the benefit of U.S. Provisional Application Ser. No. 62/021,400 filed Jul. 7, 2014, herein incorporated by reference in its entirety for all purposes.

### BACKGROUND

Electrochromic devices are optoelectrochemical systems that change their optical properties, essentially their transmittance, when a voltage is applied. As a result, the optoelectrochemical systems may be used in smart glass technologies, transitioning from translucent to transparent after the application of electricity. Transition metal oxides have been used as inorganic electrochromic materials. Among those transition metal oxides, tungsten oxide, an n-type semiconductor, is one of the most extensively studied materials due to its electrochromic properties in the visible and infrared region, high coloration efficiency and relatively low price. The color of WO₃ changes from transparent or yellow to deep blue when it is reduced under cathodic polarization.

Organic Light Emitting Diode (OLED) devices involve emission of light at a specific wavelength range when a voltage is applied. The use of transition metal oxides as the electrode interface modification layer at anode and cathode in OLEDs has also been reported for reducing the operational voltage, one of the main parameter to improve device reliability. Among those transition metal oxides, tungsten oxide or molybdenum oxide as an anode buffer layer offers advantages such as very high transparent in the visible region and energy level matching with organic molecules. (Applied Physics Letters, 2007, 91, 113506)

Typical methods of preparing tungsten oxide films for electrochromic applications, whether doped or undoped, are by using spin coating, spray coating, dip coating, or slit coating techniques starting from sol-gel nanomaterials, or related materials, making contacts with substrates like glass or plastic (J. Mater. Chem., 2010, 20, 9585-9592). Chemical Vapor Deposition or Atomic Layer Deposition techniques have also been reported as ways of preparing tungsten oxide films (Applied Organometallic Chemistry, 1998, 12, 155-160).

For OLED device manufacturing, typical methods of preparing tungsten oxide film include thermal evaporation using tungsten oxide itself. Very low pressure (<10⁻⁶ Torr) is needed to have a sufficient deposition rate which hence impacts the manufacturing cost due to necessity to maintain the vacuum process pressure by running energy-consuming pumps. (Synthetic Metals, 2005, 151, 141-146; Organic Electronics, 2009, 10, 637-642).

JP07-292079 discloses metathesis catalyst precursors having the formula M(Y)(OR²)ₓ(R³)_{y}(X)_{z}Lₛ, wherein M is Mo or W; Y is ═O or ═NR¹; R¹, R², and R³ is alkyl, cycloalkyl, cycloalkenyl, polycycloalkyl, polycycloalkenyl, haloalkyl, haloaralkyl, (un)substituted aralkyl, arom. groups containing Si; X=halogen; L=Lewis base; s=0 or 1; x+y+z=4; and y≧1. The catalyst precursor is synthesized from M(Y)(OR²)₄, such as W(═O)(OCH₂tBu)₄.

Chisholm et al. disclose preparation and characterization of oxo alkoxides of molybdenum. Inorganic Chemistry (1984) 23(8) 1021-37.

There are several publications that disclose preparation of tungsten oxide thin films.

WO2014/143410 to Kinestral Technologies Inc. discloses multi-layer electrochromic structures comprising an anodic electrochromic layer comprising lithium, nickel, and a Group 6 metal selected from Mo, W, and combinations thereof. Abstract. Para 0107 discloses that the source (starting) material for the Group 6 metal may be (RO)₄MO.

Baxter et al. disclose tungsten (VI) oxo alkoxides and tungsten (VI) oxo alkoxide beta-diketonates as volatile precursors for low pressure CVD of tungsten oxide electrochromic films, including tetraethoxy oxo tungsten, tetrakis(2-propanolato) oxo tungsten, tetrakis(2-methyl-2-propanolato) oxo tungsten, and tetrakis(2,2-dimethyl-1-propanolato) oxo tungsten. Chem. Commun. 1996, pp. 1129-1130.

WO99/23865 to Sustainable Technologies Australia Ltd. discloses that synthesis of tungsten (VI) oxo-tetra-alkoxide [WO(OR)₄] from WOCl₄, alcohol and ammonia produces an insoluble tungsten-containing compound. WO99/23865 discloses that excess ammonia can be added to dissolve the precipitated tungsten compound, but that the final tungsten oxide obtained is unsuitable as a film for electrochromic applications.

M. Basato et al. describe the use of W(═O)(OtBu)₄ by self-evaporation, in combination with H₂O, to form tungsten oxide material at 100-150° C. (Chemical Vapor Deposition, 2001, 7(5), 219-224).

J. M. Bell et al. describe the preparation of tungsten oxide film for electrochromic devices using W(═O)(OnBu)₄ (Solar Energy Materials and Solar Cells, 2001, 68, 239).

Dmitry V. Peryshkov and Richard R. Schrock describe the preparation of W(═O)(OtBu)₄ from W(═O)Cl₄ and Li(OtBu). Organometallics 2012, 31, 7278-7286.

Parkin et al. disclose CVD of Functional Coatings on Glass in Chapter 10 of Chemical Vapour Deposition: Precursors, Processes and Applications. Section 10.4.3 discloses that several tungsten alkoxides, oxo alkoxides, and aryl oxides have been investigated, such as WO(OR)₄, wherein R=Me, Et, iPr, and Bu. Parkin et al. note that these precursors provide a single source precursor, with no need for a second oxygen precursor. Parkin et al. note that these precursors suffer from low volatility.

A need remains for precursors for preparation of Group 6 containing thin films.

<Notation and Nomenclature>

Certain abbreviations, symbols, and terms are used throughout the following description and claims, and include:

As used herein, the indefinite article “a” or “an” means one or more.

As used herein, the terms “approximately” or “about” mean±10% of the value stated.

As used herein, the terms “doped” or “doping” mean to include a small amount of an additional element in the film being deposited in order to slightly alter the film's properties. For example, a doped WO₃ film may include a small amount of Li, Mo, or Na (i.e., a Li:W ratio ranging from about 0 to about 0.4; a Mo:W ratio ranging from about 0 to about 0.6; or a Na:W ratio of about 0 to about 0.3). One of ordinary skill in the art would recognize what concentration of dopant to include in the film to obtain the desired effect.

As used herein, the term “independently” when used in the context of describing R groups should be understood to denote that the subject R group is not only independently selected relative to other R groups bearing the same or different subscripts or superscripts, but is also independently selected relative to any additional species of that same R group. For example in the formula MR¹ₓ (NR²R³)(₄₋ₓ), where x is 2 or 3, the two or three R¹ groups may, but need not be identical to each other or to R² or to R³. Further, it should be understood that unless specifically stated otherwise, values of R groups are independent of each other when used in different formulas.

As used herein, the term “alkyl group” refers to saturated functional groups containing exclusively carbon and hydrogen atoms. Further, the term “alkyl group” refers to linear, branched, or cyclic alkyl groups. Examples of linear alkyl groups include without limitation, methyl groups, ethyl groups, n-propyl groups, n-butyl groups, etc. Examples of branched alkyls groups include without limitation, t-butyl. Examples of cyclic alkyl groups include without limitation, cyclopropyl groups, cyclopentyl groups, cyclohexyl groups, etc.

As used herein, the term “aryl” refers to aromatic ring compounds where one hydrogen atom has been removed from the ring. As used herein, the term “heterocycle” refers to a cyclic compound that has atoms of at least two different elements as members of its ring.

As used herein, the abbreviation “Me” refers to a methyl group; the abbreviation “Et” refers to an ethyl group; the abbreviation “Pr” refers to any propyl group (i.e., n-propyl or isopropyl); the abbreviation “iPr” refers to an isopropyl group; the abbreviation “Bu” refers to any butyl group (n-butyl, iso-butyl, t-butyl, sec-butyl); the abbreviation “tBu” refers to a tert-butyl group; the abbreviation “sBu” refers to a sec-butyl group; the abbreviation “iBu” refers to an iso-butyl group; the abbreviation “Pe” refers to a pentyl group; the abbreviation “Ph” refers to a phenyl group; the abbreviation “Am” refers to any amyl group (iso-amyl, sec-amyl, tert-amyl); and the abbreviation “Cy” refers to a cyclic alkyl group (cyclobutyl, cyclopentyl, cyclohexyl, etc.).

### SUMMARY

Disclosed are group 6 film forming compositions comprising a liquid precursor having the formula M(═O)(OR)₄, wherein M is Mo or W and each R is independently selected from the group consisting of tBu, sBu, CH₂sBu, CH₂iBu, CH(Me)(iPr), CH(Me)(nPr), CH(Et)₂, C(Me)₂(Et), a C6-C8 alkyl group, and combinations thereof, provided that every R is tBu only when M is Mo. The disclosed compositions may include one or more of the following aspects:
the liquid precursor being Mo(═O)(OtBu)₄;
the liquid precursor being Mo(═O)(OsBu)₄;
the liquid precursor being Mo(═O)(OiBu)₄;
the liquid precursor Mo(═O)(OCH₂R)₄, wherein each R is independently sBu or iBu;
the liquid precursor Mo(═O)(OCH₂sBu)₄;
the liquid precursor Mo(═O)(OCH₂iBu)₄;
the liquid precursor Mo(═O)(OCH₂nBu)₄;
the liquid precursor Mo(═O)(OCH(Me)(iPr))₄;
the liquid precursor Mo(═O)(OCH(Me)(nPr))₄;
the liquid precursor Mo(═O)(OCH(Et)₂)₄;
the liquid precursor Mo(═O)(OC(Me)₂(Et))₄;
the liquid precursor Mo(═O)(OR)₄, wherein at least one R is a C6-C8 alkyl chain.
the liquid precursor being W(═O)(OsBu)₄;
the liquid precursor having the formula W(═O)(OCH₂R)₄, wherein each R is independently sBu or iBu;
the liquid precursor being W(═O)(OCH₂sBu)₄;
the liquid precursor being W(═O)(OCH₂iBu)₄;
the liquid precursor being W(═O)(OCH₂nBu)₄;
the liquid precursor being W(═O)(OCH(Me)(iPr))₄;
the liquid precursor being W(═O)(OCH(Me)(nPr))₄;
the liquid precursor being W(═O)(OCH(Et)₂)₄;
the liquid precursor being W(═O)(OC(Me)₂(Et))₄.
the liquid precursor having the formula W(═O)(OR)₄, wherein at least one R is a C6-C8 alkyl chain;
the composition comprising between approximately 0.1 molar % and approximately 50 molar % of the liquid precursor;
the composition comprising between approximately 0 atomic % and 5 atomic % of M(OR)₆;
the composition comprising between approximately 0 ppmw and 200 ppm of Cl;
further comprising a solvent.
the solvent being selected from the group consisting of C1-C16 hydrocarbons, THF, DMO, ether, pyridine, and combinations thereof;
the solvent being a C1-C16 hydrocarbons;
the solvent being tetrahydrofuran (THF);
the solvent being dimethyl oxalate (DMO);
the solvent being ether;
the solvent being pyridine;
the solvent being ethanol; or
the solvent being isopropanol.

Also disclosed are methods of forming Group 6-containing films on substrates. A solution comprising any of the Group 6 film forming compositions disclosed above is formed and contacted with the substrate via a spin coating, spray coating, dip coating, or slit coating technique to form the Group-6 containing film. The disclosed methods may include the following aspects:
annealing the Group-6 containing film; or
laser treating the Group-6 containing film.

Also disclosed are methods of forming Group 6-containing films on substrates. A vapor of any of the Group 6 film forming compositions disclosed above is introduced into a reactor having the substrate therein and at least part of the precursor is deposited onto the substrate to form the Group 6-containing film. The disclosed methods may include the following aspects:
introducing a reactant into the reactor;
the reactant being selected from the group consisting of O₂, O₃, H₂O, H₂O₂, NO, N₂O, NO₂, oxygen radicals thereof, and mixtures thereof; or
annealing the Group-6 containing film.

### BRIEF DESCRIPTION OF DRAWINGS

For a further understanding of the nature and objects of the present invention, reference should be made to the following detailed description, taken in conjunction with the accompanying drawings, in which like elements are given the same or analogous reference numbers and wherein:

FIG. 1 is a block diagram that schematically illustrates an exemplary CVD apparatus;

FIG. 2 is a ¹H-NMR spectrum of W(═O)(OsBu)₄;

FIG. 3 is a ¹³C-NMR spectrum of W(═O)(OsBu)₄;

FIG. 4 is a ThermoGravimetric-Differential Thermal Analysis (TG-DTA) graph demonstrating the percentage of weight loss (TG) and the differential temperature (DT) with increasing temperature of W(═O)(OsBu)₄;

FIG. 5 is a ¹H-NMR spectrum of W(═O)(OCH(CH₃)(CH(CH₃)₂))₄;

FIG. 6 is a ¹³C-NMR spectrum of W(═O)(OCH(CH₃)(CH(CH₃)₂))₄;

FIG. 7 is a TG-DTA graph demonstrating the percentage of weight loss (TG) and the differential temperature (DT) with increasing temperature of W(═O)(OCH(CH₃) (CH(CH₃)₂))₄;

FIG. 8 is a ¹H-NMR spectrum of W(═O)(OCH(CH₃)₂)₄;

FIG. 9 is a TG-DTA graph demonstrating the percentage of weight loss (TG) and the differential temperature (DT) with increasing temperature of W(═O)(OCH(CH₃)₂)₄;

FIG. 10 is a TG-DTA graph demonstrating the percentage of weight loss (TG) and the differential temperature (DT) with increasing temperature of W(═O)(OnPr)₄;

FIG. 11 is a ¹H-NMR spectrum of W(═O)(OCH₂CH(CH₃)₂)₄;

FIG. 12 is a TG-DTA graph demonstrating the percentage of weight loss (TG) and the differential temperature (DT) with increasing temperature of W(═O)(OCH₂CH(CH₃)₂)₄;

FIG. 13 is a TG-DTA graph demonstrating the percentage of weight loss (TG) and the differential temperature (DT) with increasing temperature of W(═O)(OnBu)₄;

FIG. 14 is a Scanning Electron Microscope (SEM) photo of a tungsten oxide layer deposited on a substrate by dipcoating the substrate in a mixture of W(═O)(OsBu)₄, H₂O₂ and EtOH;

FIG. 15 is a SEM photo of a tungsten oxide layer deposited on a substrate by dipcoating the substrate in a mixture of W(═O)(OCH(Me)(iPr))₄, H₂O₂ and EtOH;

FIG. 16 is a SEM photo of a tungsten oxide layer deposited on a substrate by dipcoating the substrate in a mixture of W(═O)(OCH(Me)(iPr))₄, H₂O₂ and EtOH;

FIG. 17 is a SEM photo of a tungsten oxide layer deposited on a substrate by dipcoating the substrate in a mixture of W(═O)(OnPr)₄, H₂O₂ and EtOH;

FIG. 18 is a SEM photo of a tungsten oxide layer deposited on a substrate by dipcoating the substrate in a mixture of W(═O)(OnPr)₄, H₂O₂ and EtOH;

FIG. 19 is a SEM photo of a tungsten oxide layer deposited on a substrate by dipcoating the substrate in a mixture of W(═O)(OiBu)₄, H₂O₂ and EtOH;

FIG. 20 is a SEM photo of a tungsten oxide layer deposited on a substrate by Chemical Vapor Deposition (CVD) using oxygen and W(═O)(OsBu)₄; and

FIG. 21 is a SEM photo of a tungsten oxide layer deposited on a substrate by CVD using oxygen and W(═O)(OsBu)₄.

### DESCRIPTION OF EMBODIMENTS

Disclosed are group 6 film forming compositions comprising a liquid precursor having the formula M(═O)(OR)₄, wherein M is Mo or W and each R is independently selected from the group consisting of tBu, sBu, CH₂sBu, CH₂iBu, CH(Me)(iPr), CH(Me)(nPr), CH(Et)₂, C(Me)₂(Et), a C6-C8 alkyl group, and combinations thereof, provided that every R is tBu only when M is Mo.

Exemplary liquid tungsten precursors include W(═O)(OsBu)₄; W(═O)(OCH₂R)₄, wherein each R is independently sBu or iBu; W(═O)(OCH(Me)(iPr))₄; W(═O)(OCH(Me)(nPr))₄; W(═O)(OCH(Et)₂)₄; W(═O)(OC(Me)₂(Et))₄; or W(═O)(OR)₄, wherein at least one R is a C6-C8 alkyl chain.

Exemplary liquid molybdenum precursors include Mo(═O)(OtBu)₄; Mo(═O)(OsBu)₄; Mo(═O)(OiBu)₄; Mo(═O)(OCH₂R)₄, wherein each R is independently sBu or iBu; Mo(═O)(OCH(Me)(iPr))₄; Mo(═O)(OCH(Me)(nPr))₄; Mo(═O)(OCH(Et)₂)₄; Mo(═O)(OC(Me)₂(Et))₄; or Mo(═O)(OR)₄, wherein at least one R is a C6-C8 alkyl chain.

Applicants believe that alkyl groups having longer carbon chains may help to reduce the melting point of the precursor. Preferably the alkyl chain is branched, and more preferably branched in an unsymmetric manner (such as in —CH(Me)(iPr)). Asymmetric M(═O)(OR)₄ precursors may also help to reduce the melting point, for example by using different alkoxy ligands on the precursor (such as W(═O)(OCH(Me)(iPr))₂(OsBu)₂).

The liquid phase of the disclosed Group VI oxo alkoxide precursors may permit the precursors to be easily incorporated in a variety of liquid mixtures, such as those disclosed at paras 0102-0103 and 0109 of WO2014/143410 to Kinestral Technologies, Inc. In contrast, as shown in the examples that follow, many of the solid Group VI oxo alkoxide precursors suffer from solubility constraints that may make them less capable of incorporation into such liquid mixtures. More particularly, the solids of comparative examples 1-4 were found to have low solubility in alkanes and toluene. The disclosed liquid precursors will be more easily incorporated into the alkane or non-polar aprotic solvent systems disclosed in WO2014/143410 because they require little to no dissolution time as compared to the solid analogs that have low solubility in these solvents. As a result, the disclosed liquid precursors help to make the anodic electrochromic layer preparation quicker and more efficient.

The disclosed group 6 film forming compositions comprising a liquid M(═O)(OR)₄ precursor may be synthesized by reacting W(═O)X₄ with 4 equivalents of M^{a}OR, wherein X is a halide, preferably Cl; M^{a} is an alkali metal, such as Li or Na, and preferably Na; and R is defined above. Similarly, Mo(═O)(OR)₄ may be prepared from Mo(═O)X₄ and M^{a}OR, with X, Ma, and R as defined. W(═O)X₄ may be prepared as described by Vernon C. Gibson et al., Polyhedron (1988), 7, 7, 579. Mo(═O)Cl₄ is commercially available. The reaction may be done at low temperature, the temperature being below −50° C. The reaction may be done in a polar solvent, such as THF or di-ethylether. The precursor may be separated from alkali salts by extraction with a non polar solvent, such as pentane, hexane, cyclohexane, heptanes, benzene and toluene. The resulting group 6 film forming composition may be purified by distillation and/or passing the liquid through a suitable adsorbent, such as a 4A molecular sieve.

The prior art solid M(═O)(OR)₄ precursors are purified using sublimation. Sublimation processes are known to be difficult to scale-up and to industrialize in a cost-effective manner. Distillation may be used as the purification method for the disclosed liquid precursors, instead of sublimation, making industrial production easier. Liquid and solid precursors having a low-melting point (i.e., <80° C.) may be purified using distillation, as opposed to sublimation for solid precursors having higher melting points (i.e., >80° C.). Distillation typically produces a lower amount of impurities in the final product. As a result, films produced from liquid precursors may contain less impurities than films produced from solid precursors. The solid precursors may also contain residual halide from the reactants. Halides are detrimental to the photochromic performance of the film.

Purity of the disclosed group 6 film forming composition is greater than 95% w/w (i.e., 95.0% w/w to 100.0% w/w), preferably greater than 98% w/w (i.e., 98.0% w/w to 100.0% w/w), and more preferably greater than 99% w/w (i.e., 99.0% w/w to 100.0% w/w). One of ordinary skill in the art will recognize that the purity may be determined by H NMR or gas or liquid chromatography with mass spectrometry. The disclosed group 6 film forming composition may contain any of the following impurities: M(OR)₆; M(═O)X₄; M^{a}OR; THF; ether; pentane; cyclohexane; heptanes; benzene; toluene; or halogenated metal compounds. The total quantity of these impurities is below 5% w/w (i.e., 0.0% w/w to 5.0% w/w), preferably below 2% w/w (i.e., 0.0% w/w to 2.0% w/w), and more preferably below 1% w/w (i.e. 0.0% w/w to 1.0% w/w).

Purification of the disclosed group 6 film forming composition may also result in halide concentrations between approximately 0 ppmw and 200 ppmw, preferably between approximately 0 ppmw and 100 ppmw.

Purification of the disclosed group 6 film forming composition may also result in metal impurities at the 0 ppbw to 1 ppmw, preferably 0-500 ppbw (part per billion weight) level. These metal impurities include, but are not limited to, Aluminum (Al), Arsenic (As), Barium (Ba), Beryllium (Be), Bismuth (Bi), Cadmium (Cd), Calcium (Ca), Chromium (Cr), Cobalt (Co), Copper (Cu), Gallium (Ga), Germanium (Ge), Hafnium (Hf), Zirconium (Zr), Indium (In), Iron (Fe), Lead (Pb), Lithium (Li), Magnesium (Mg), Manganese (Mn), Tungsten (W), Nickel (Ni), Potassium (K), Sodium (Na), Strontium (Sr), Thorium (Th), Tin (Sn), Titanium (Ti), Uranium (U), and Zinc (Zn).

The disclosed Group 6 film forming composition may further include a solvent, such as C1-C16 hydrocarbons, alcohols, toluene, THF, DMO, ether, pyridine, and combinations thereof.

The disclosed Group 6 film forming compositions may be used to form Group 6 films using any of the methods known in the art. For example, the disclosed Group 6 film forming compositions may be used in spin coating, spray coating, dip coating, or slit coating techniques, making contacts with substrates like glass or plastic. J. Mater. Chem., 2010, 20, 9585-9592.

Exemplary dip coating methods are provided in the examples that follow. More particularly, the disclosed Group 6 film forming compositions may be included in a solution into which a substrate is dipped, such as ethanol or isopropanol. Group 4, 5, and/or 6 precursors, such as a Ti methoxide, may be added to the solution in order to modify the optical and/or electrical properties of the resulting film. The resulting film may be dried at room temperature for a period of time to vaporize the solvent. During the drying process, a mist of water may be sprayed onto the substrate to promote hydrolysis reaction of the film.

The sol-gel derived WO₃ films typically do not exhibit electrochromism until they are annealed or laser-fired. Kirss et al., Applied Organometallic Chemistry, Vol. 12, 1550160 (1998). Therefore, the resulting film may be exposed to high temperatures or laser treatment for a period of time. The dipping and annealing/laser firing process may be repeated to obtain films having the desired thickness.

Other sol-gel processes like spin-coating may use a similar approach, with potential alterations in the viscosities and oxide concentration of the solutions.

The liquid form of the disclosed Group 6 film forming compositions may also make them suitable for vapor deposition processes, such as Atomic Layer Deposition or Chemical Vapor Deposition. Exemplary CVD methods include thermal CVD, plasma enhanced CVD (PECVD), pulsed CVD (PCVD), low pressure CVD (LPCVD), sub-atmospheric CVD (SACVD) or atmospheric pressure CVD (APCVD), hot-wire CVD (HWCVD, also known as cat-CVD, in which a hot wire serves as an energy source for the deposition process), radicals incorporated CVD, and combinations thereof. Exemplary ALD methods include thermal ALD, plasma enhanced ALD (PEALD), spatial isolation ALD, hot-wire ALD (HWALD), radicals incorporated ALD, and combinations thereof. Super critical fluid deposition may also be used. The deposition method is preferably ALD, PE-ALD, or spatial ALD in order to provide suitable step coverage and film thickness control.

The liquid Group 6 film forming compositions may be used in the vapor deposition process either in neat form or blended with a suitable solvent, such as hexane, heptanes, octane and butyl acetate. The neat or blended Group 6 film forming compositions are introduced into a reactor in vapor form by conventional means, such as tubing and/or flow meters. The vapor form may be produced by vaporizing the neat or blended composition through a conventional vaporization step such as direct vaporization, distillation, or by bubbling. A liquid mass flow controller may feed the neat or blended composition may be fed in liquid state to a vaporizer where it is vaporized before it is introduced into the reactor. Alternatively the neat or blended composition may be supplied by self-evaporation and the flow rates controlled by a mass flow controller. In another alternative, the neat or blended composition may be vaporized by passing a carrier gas into a container containing the composition or by bubbling the carrier gas into the composition. The carrier gas may include, but is not limited to, Ar, He, N₂, and mixtures thereof. Bubbling with a carrier gas may also remove any dissolved oxygen present in the neat or blended composition. The carrier gas and composition are then introduced into the reactor as a vapor.

If necessary, the container containing the disclosed composition may be heated to a temperature that permits the composition to be in its liquid phase and to have a sufficient vapor pressure. The container may be maintained at temperatures in the range of, for example, approximately 0° C. to approximately 150° C. Those skilled in the art recognize that the temperature of the container may be adjusted in a known manner to control the amount of precursor vaporized.

The reactor may be any enclosure or chamber within a device in which vapor deposition methods take place such as without limitation, a parallel-plate type reactor, a cold-wall type reactor, a hot-wall type reactor, a single-wafer reactor, a multi-wafer reactor, or other types of deposition systems under conditions suitable to cause the compounds to react and form the layers. One of ordinary skill in the art will recognize that any of these reactors may be used for either ALD or CVD deposition processes.

The reactor contains one or more substrates onto which the films will be deposited. A substrate is generally defined as the material on which a process is conducted. The substrates may be any suitable substrate used in semiconductor, photovoltaic, flat panel, or LCD-TFT device manufacturing. Examples of suitable substrates include wafers, such as silicon, silica, glass, or GaAs wafers. The wafer may have one or more layers of differing materials deposited on it from a previous manufacturing step. One of ordinary skill in the art will recognize that the terms “film” or “layer” used herein refer to a thickness of some material laid on or spread over a surface and that the surface may be a trench or a line. Throughout the specification and claims, the wafer and any associated layers thereon are referred to as substrates.

The temperature and the pressure within the reactor are held at conditions suitable for vapor depositions. In other words, after introduction of the vaporized composition into the chamber, conditions within the chamber are such that at least part of the precursor is deposited onto the substrate to form a Group VI film. For instance, the pressure in the reactor may be held between about 1 Pa and about 10⁵ Pa, more preferably between about 25 Pa and about 10³ Pa, as required per the deposition parameters. Likewise, the temperature in the reactor may be held between about 100° C. and about 500° C., preferably between about 150° C. and about 400° C. One of ordinary skill in the art will recognize that “at least part of the precursor is deposited” means that some or all of the precursor reacts with or adheres to the substrate.

The temperature of the reactor may be controlled by either controlling the temperature of the substrate holder or controlling the temperature of the reactor wall. Devices used to heat the substrate are known in the art. The reactor wall is heated to a sufficient temperature to obtain the desired film at a sufficient growth rate and with desired physical state and composition. A non-limiting exemplary temperature range to which the reactor wall may be heated includes from approximately 20° C. to approximately 700° C. When a plasma deposition process is utilized, the deposition temperature may range from approximately 20° C. to approximately 100° C. Alternatively, when a thermal process is performed, the deposition temperature may range from approximately 200° C. to approximately 700° C.

In addition to the disclosed Group 6 film forming compositions, a reactant may be introduced into the reactor. The reactant may be H₂, H₂CO, N₂H₄, NH₃, SiH₄, Si₂H₆, Si₃H₈, SiH₂Me₂, SiH₂Et₂, N(SiH₃)₃, hydrogen radicals thereof, and mixtures thereof. Preferably, the reactant is H₂ or NH₃.

Alternatively, the reactant may be an oxidizing gas such as one of O₂, O₃, H₂O, H₂O₂, NO, N₂O, NO₂, oxygen containing radicals such as O. or OH., carboxylic acids, formic acid, acetic acid, propionic acid, and mixtures thereof. Preferably, the oxidizing gas is selected from the group consisting of O₂, O₃, or H₂O. It is also possible to prepare a Group VI oxide film through the introduction of the Group 6 film forming compositions into the reactor chamber, but the concomitant use of an oxygen source, typically oxygen or ozone is preferred.

The reactant may be treated by a plasma, in order to decompose the reactant into its radical form. N₂ may also be utilized as a nitrogen source gas when treated with plasma. For instance, the plasma may be generated with a power ranging from about 50 W to about 500 W, preferably from about 100 W to about 400 W. The plasma may be generated or present within the reactor itself. Alternatively, the plasma may generally be at a location removed from the reactor, for instance, in a remotely located plasma system. One of skill in the art will recognize methods and apparatus suitable for such plasma treatment.

For example, the reactant may be introduced into a direct plasma reactor, which generates plasma in the reaction chamber, to produce the plasma-treated reactant in the reaction chamber. Exemplary direct plasma reactors include the Titan™ PECVD System produced by Trion Technologies. The reactant may be introduced and held in the reaction chamber prior to plasma processing. Alternatively, the plasma processing may occur simultaneously with the introduction of the reactant. In-situ plasma is typically a 13.56 MHz RF inductively coupled plasma that is generated between the showerhead and the substrate holder. The substrate or the showerhead may be the powered electrode depending on whether positive ion impact occurs. Typical applied powers in in-situ plasma generators are from approximately 30 W to approximately 1000 W. Preferably, powers from approximately 30 W to approximately 600 W are used in the disclosed methods. More preferably, the powers range from approximately 100 W to approximately 500 W. The disassociation of the reactant using in-situ plasma is typically less than achieved using a remote plasma source for the same power input and is therefore not as efficient in reactant disassociation as a remote plasma system, which may be beneficial for the deposition of Group VI films on substrates easily damaged by plasma.

Alternatively, the plasma-treated reactant may be produced outside of the reaction chamber. The MKS Instruments' ASTRONi® reactive gas generator may be used to treat the reactant prior to passage into the reaction chamber. Operated at 2.45 GHz, 7 kW plasma power, and a pressure ranging from approximately 0.5 Torr to approximately 10 Torr, the reactant O₂ may be decomposed into two O. radicals. Preferably, the remote plasma may be generated with a power ranging from about 1 kW to about 10 kW, more preferably from about 2.5 kW to about 7.5 kW.

The vapor deposition conditions within the chamber allow the disclosed composition and the reactant to react and form a Group VI containing film on the substrate. In some embodiments, Applicants believe that plasma-treating the reactant may provide the reactant with the energy needed to react with the disclosed composition.

Depending on what type of film is desired to be deposited, an additional precursor compound may be introduced into the reactor. The precursor may be used to provide additional elements to the Group VI containing film. The additional elements may include lanthanides (Ytterbium, Erbium, Dysprosium, Gadolinium, Praseodymium, Cerium, Lanthanum, Yttrium), zirconium, germanium, silicon, magnesium, titanium, manganese, ruthenium, bismuth, lead, magnesium, aluminum, or mixtures of these. When an additional precursor compound is utilized, the resultant film deposited on the substrate contains the Group 6 transition metal in combination with an additional element.

The Group 6 film forming compositions and reactants may be introduced into the reactor either simultaneously (chemical vapor deposition), sequentially (atomic layer deposition) or different combinations thereof. The reactor may be purged with an inert gas between the introduction of the compositions and the introduction of the reactants. Alternatively, the reactants and the compositions may be mixed together to form a reactant/composition mixture, and then introduced to the reactor in mixture form. Another example is to introduce the reactant continuously and to introduce the Group 6 film forming composition by pulse (pulsed chemical vapor deposition).

The vaporized composition and the reactant may be pulsed sequentially or simultaneously (e.g. pulsed CVD) into the reactor. Each pulse of composition may last for a time period ranging from about 0.01 seconds to about 10 seconds, alternatively from about 0.3 seconds to about 3 seconds, alternatively from about 0.5 seconds to about 2 seconds. In another embodiment, the reactant may also be pulsed into the reactor. In such embodiments, the pulse of each may last for a time period ranging from about 0.01 seconds to about 10 seconds, alternatively from about 0.3 seconds to about 3 seconds, alternatively from about 0.5 seconds to about 2 seconds. In another alternative, the vaporized compositions and reactants may be simultaneously sprayed from a shower head under which a susceptor holding several wafers is spun (spatial ALD).

Depending on the particular process parameters, deposition may take place for a varying length of time. Generally, deposition may be allowed to continue as long as desired or necessary to produce a film with the necessary properties. Typical film thicknesses may vary from several angstroms to several hundreds of microns, depending on the specific deposition process. The deposition process may also be performed as many times as necessary to obtain the desired film.

In one non-limiting exemplary CVD process, the vapor phase of the disclosed Group 6 film forming composition and a reactant are simultaneously introduced into the reactor. The two react to form the resulting Group VI containing film. When the reactant in this exemplary CVD process is treated with a plasma, the exemplary CVD process becomes an exemplary PECVD process. The reactant may be treated with plasma prior or subsequent to introduction into the chamber.

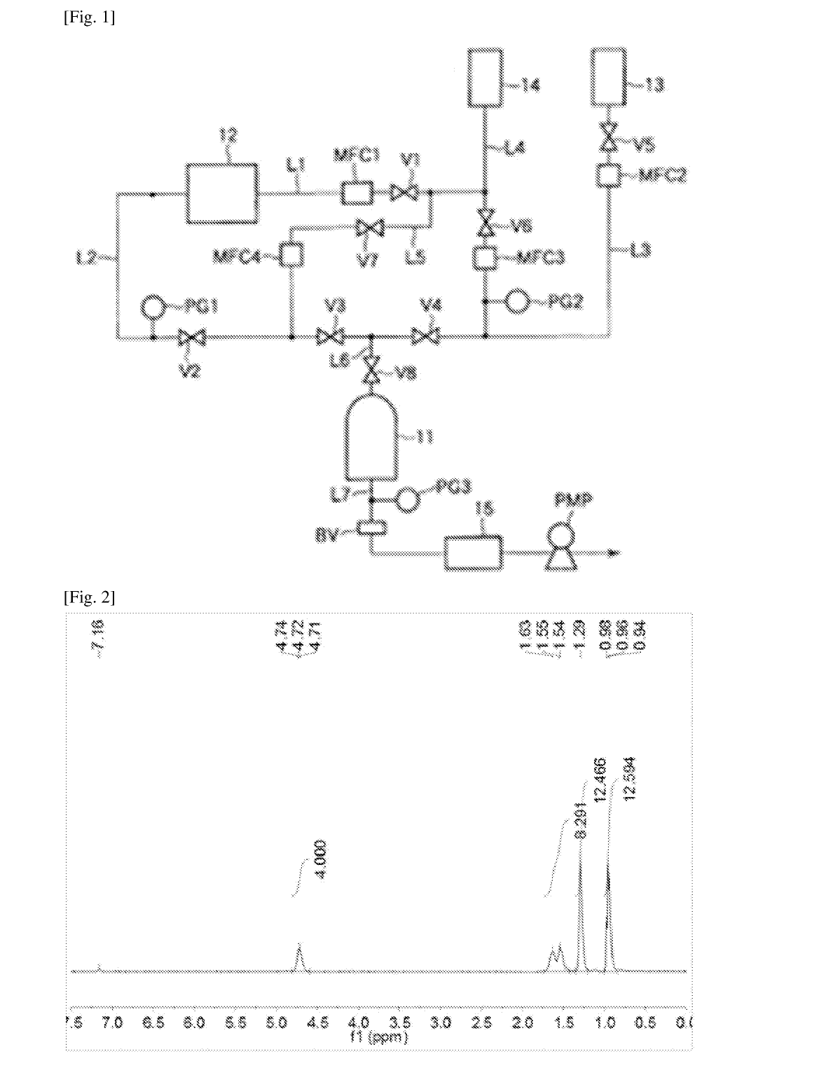

FIG. 1 is a block diagram that schematically illustrates an example of a CVD-based apparatus that can be used to execute the inventive method for electrochromic devices. The apparatus illustrated in FIG. 1 includes a reaction chamber 11, a feed source 12 for a volatile tungsten precursor, a feed source 13 for an oxidizing agent gas (typically oxygen or ozone), and a feed source 14 for an inert gas that can be used as a carrier gas and/or dilution gas. A substrate loading and unloading mechanism (not shown) allows the insertion and removal of deposition substrates in the reaction chamber 11. A heating device (not shown) is provided to reach the reaction temperatures required for reaction of the precursors.

The volatile tungsten precursor feed source 12 may use a bubbler method to introduce the volatile tungsten precursor into the reaction chamber 11, and is connected to the inert gas feed source 14 by the line L1. The line L1 is provided with a shutoff valve V1 and a flow rate controller, for example, a mass flow controller MFC1, downstream from this valve. The volatile tungsten precursor is introduced from its feed source 12 through the line L2 into the reaction chamber 11. The following are provided on the upstream side: a pressure gauge PG1, a shutoff valve V2, and a shutoff valve V3.

The oxidizing agent gas feed source 13 comprises a vessel that holds the oxidizing agent in gaseous form. The oxidizing agent gas is introduced from its feed source 13 through the line L3 into the reaction chamber 11. A shutoff valve V4 is provided in the line L3. This line L3 is connected to the line L2.

The inert gas feed source 14 comprises a vessel that holds inert gas in gaseous form. The inert gas can be introduced from its feed source through the line L4 into the reaction chamber 11. Line L4 is provided with the following on the upstream side: a shutoff valve V6, a mass flow controller MFC3, and a pressure gauge PG2. The line L4 joins with the line L3 upstream from the shutoff valve V4.

The line L5 branches off upstream from the shutoff valve V1 in the line L; this line L5 joins the line L2 between the shutoff valve V2 and the shutoff valve V3. The line L5 is provided with a shutoff valve V7 and a mass flow controller MFC4 considered from the upstream side.

The line L6 branches off between the shutoff valves V3 and V4 into the reaction chamber 11. This line L6 is provided with a shutoff valve V8.

A line L7 that reaches to the pump PMP is provided at the bottom of the reaction chamber 11. This line L7 contains the following on the upstream side: a pressure gauge PG3, a butterfly valve BV for controlling the backpressure, and a cold trap 15. This cold trap 15 comprises a tube (not shown) that is provided with a cooler (not shown) over its circumference and is aimed at collecting the tungsten precursor and the related by-products.

The production of electrochromic devices using the apparatus illustrated in FIG. 1 commences with the closing of shutoff valves Vi, V2, and V5 and the opening of shutoff valves V6, V7, V3, V4, and V8 and the introduction of inert gas by the action of the pump PMP from the inert gas feed source 14 through the line L4 into the line L6 and into the reaction chamber 11.

The shutoff valve V5 is then opened and oxidizing agent gas is introduced into the reaction chamber 11 from the oxidizing agent gas feed source 13. The shutoff valves V1 and V2 are opened and inert gas is introduced from the inert gas feed source 14 through the line L1 and into the volatile tungsten precursor feed source 12. This results in the introduction of gaseous tungsten precursor through the line L2 and the line L6 into the reaction chamber 11. The oxidizing agent gas and tungsten compound react in the reaction chamber 11, resulting in the formation of a tungsten oxide coating over the glass substrate.

In one non-limiting exemplary ALD process, the vapor phase of the disclosed Group 6 film forming composition is introduced into the reactor, where it is contacted with a suitable substrate. Excess composition may then be removed from the reactor by purging and/or evacuating the reactor. A reactant (for example, O₃) is introduced into the reactor where it reacts with the absorbed composition in a self-limiting manner. Any excess reactant is removed from the reactor by purging and/or evacuating the reactor. If the desired film is a tungsten oxide, this two-step process may provide the desired film thickness or may be repeated until a film having the necessary thickness has been obtained.

Upon obtaining a desired film thickness, the film may be subject to further processing, such as thermal annealing, furnace-annealing, rapid thermal annealing, UV or e-beam curing, and/or plasma gas exposure. Those skilled in the art recognize the systems and methods utilized to perform these additional processing steps. For example, the NbN film may be exposed to a temperature ranging from approximately 200° C. and approximately 1000° C. for a time ranging from approximately 0.1 second to approximately 7200 seconds under an inert atmosphere, a N-containing atmosphere, or combinations thereof. Most preferably, the temperature is 400° C. for 3600 seconds under an inert atmosphere or a N-containing atmosphere. The resulting film may contain fewer impurities and therefore may have an improved density resulting in improved leakage current. The annealing step may be performed in the same reaction chamber in which the deposition process is performed. Alternatively, the substrate may be removed from the reaction chamber, with the annealing/flash annealing process being performed in a separate apparatus. Any of the above post-treatment methods, but especially thermal annealing, has been found effective to help produce the electrochromic properties of the Group VI oxide film.

The disclosed Group 6 film forming compositions may be used to form MO₃ films, or doped MO₃ films, for electrochromic applications so that a minimal number of optical defects are present in the electrochromic windows. Applicants believe that the liquid precursors may be used to deposit electrochromic MO₃ films having a larger color efficiency (i.e., the change of optical density per unit of charge of insertion or extraction) and faster response times than films deposited by the analogous oxo tungsten akoxides. Applicants also believe that MO₃ films produced by the liquid precursors may undergo more color/bleaching cycles than those produced by the analogous oxo tungsten alkoxides.

The disclosed Group 6 film forming compositions may also be used to form MO₃ films, or doped MO₃ films, for OLEDs applications so that a minimal number of defects are present in the anode buffer layer.

### EXAMPLES

The following non-limiting examples are provided to further illustrate embodiments of the invention. However, the examples are not intended to be all inclusive and are not intended to limit the scope of the inventions described herein.

### Synthesis Example 1: W(═O)(Osbu)₄

A 2 L three neck flask equipped with a stirrer was evacuated and replaced therein by nitrogen. A solution of anhydrous sec-butanol (485 mmol, 35.93 g) in dry toluene (200 mL) and dry tetrahydrofuran (160 mL) was introduced into the flask and cooled to 0° C., and n-butyllithium (1.63 M in hexane, 480 mmol, 295 mL) was added dropwise with stirring. The reaction was warmed to room temperature and stirred for two hours. A slurry of tungsten(VI) oxytetrachloride (120 mmol, 41 g) in dry toluene (530 mL) was cooled to 0° C. and the lithium sec-butoxide solution was added over a one hour period. The mixture was warmed to room temperature and stirred overnight. Filtration at room temperature through Celite® brand diatomaceous earth was performed in order to remove LiCl salt. The solvent was removed under vacuum on an oil batch at 40° C. and the resulting green liquid was purified by distillation under a reduced pressure (90 mTorr) at 90° C. As a result, supported from the characterizations shown below, 43 g of W(═O)(OsBu)₄ as a pale yellow liquid were obtained (87 mmol, yield=73% based on the tungsten(VI) oxytetrachloride).

Typically, the melting point decreases by changing the form of the alkyl branch. tBu typically leads to the highest melting point, iBu, nBu to lower melting points. The surprise here is that the melting point does not go into that direction, so getting a liquid with sBu is counter-intuitive. As a result, W(═O)(OsBu)₄ is not subject to the same solubility issues encountered by the other tungsten(VI) oxo tetraalkoxides, which allows room temperature filtration and reduction by 2 times the quantity of solvent used. Moreover distillation may be used as the purification method, instead of sublimation, which eases its industrial production. Liquid and solid precursors having a low-melting point (i.e., <80° C.) may be purified using distillation, as opposed to sublimation for solid precursors having higher melting points (i.e., >80° C.). Distillation typically produces a lower amount of impurities in the final product. As a result, films produced from liquid precursors may contain less impurities than films produced from solid precursors. In this case, the solid precursors may contain residual chlorine from the reactants. Chlorine is detrimental to the photochromic performance of the film.

The yield of the synthesis was assessed with different amounts of starting materials: 2 g of tungsten(VI) oxytetrachloride (5.85 mmol) and 1.87 g of lithium sec-butoxide (23.4 mmol) were engaged and 2.02 g of W(═O)(OsBu)₄ were obtained (4.10 mmol, yield=70% based on tungsten(VI) oxytetrachloride). W(═O)(OsBu)₄ synthesis was performed as described in the Comparative Example 1 below. The yield was noticeably improved, which proves again the easiness of W(═O)(OsBu)₄ synthesis, thus allowing an easier industrial-scale production method.

Analysis of the Compound:
The ¹H-NMR spectrum is provided in FIG. 2. In order to transform the figures in the provisional application from color to black and white, the peak picking, integration and proton numbers have been recalculated.

Measurement Conditions:
Unit: Jeol (400 MHz)
Solvent: C₆D₆
Method: 1D

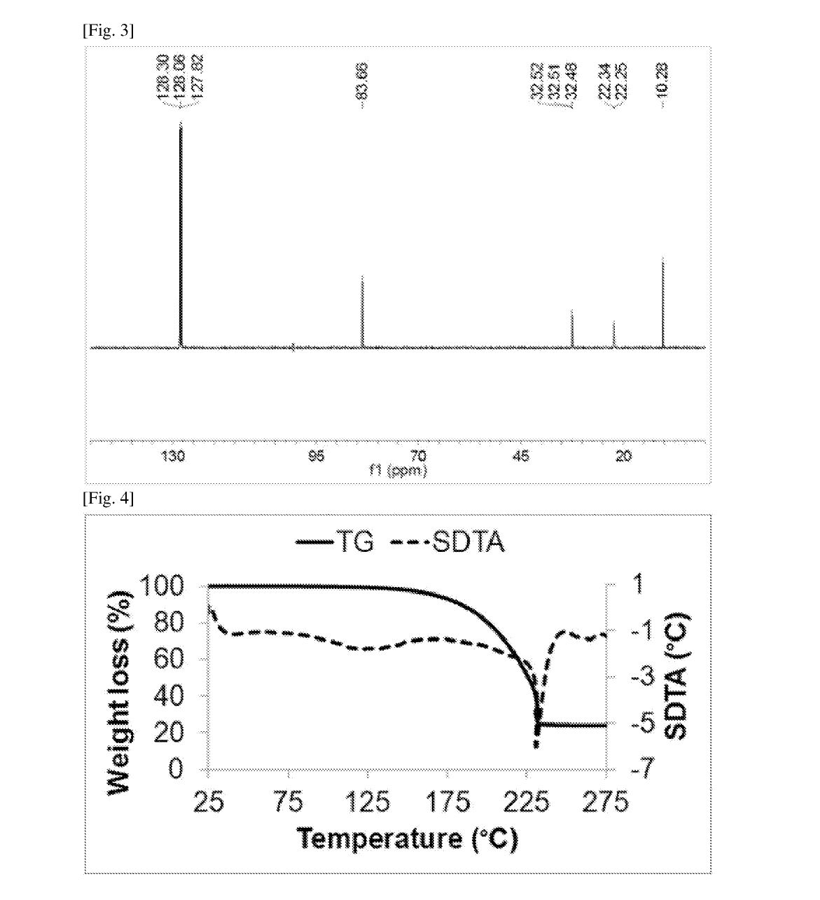

δ_{H}: 4.72 (m, OCH(CH₃)CH₂CH₃)₄, 4H), 1.55 (m, OCH(CH₃)CH₂CH₃)₄, 4H), 1.29 (m, OCH(CH₃)CH₂CH₃)₄, 4H), 1.29 (broad s, OCH(CH₃)CH₂CH₃)₄, 12H), 0.96 (m, OCH(CH₃)CH₂CH₃)₄, 12H)
The ¹³C NMR spectrum is provided in FIG. 3. In order to transform the figures in the provisional application from color to black and white, the peak picking, integration and carbon numbers have been recalculated.

Measurement Conditions:
Unit: Jeol (400 MHz)
Solvent: C₆D₆
Method: 1D

δ_{C}: (s, 83.66), (t, 32.51), (d, 22.30), (s, 10.28)
Vapor pressure: 1 Torr at 123° C.
Pale yellow liquid and its boiling point is 235° C.
The ThermoGravimetric-Differential Thermal Analysis (TG-DTA) graph is provided in FIG. 4.

Measurement Conditions:
Sample weight: 26.00 mg
Atmosphere: Nitrogen, 1 atmospheric pressure
Heating rate: 10° C.·min⁻¹
   Solubility of the compound in common solvents

W(═O)(OsBu)₄ is miscible with common organic solvents such as hexane, acetone, chloroform, and/or toluene.

Thermal Stability Test

The product was stored at 50° C. for 14 and 44 days. The W(OsBu)₆ content after 14 days was 1.1 atomic %. The W(OsBu)₆ content after 44 days was 1.2 atomic %. This shows that the product has a suitable shelf life for storage and transportation.

### Synthesis Example 2: W(═O)(OCH(CH₃)(CH(CH₃)₂))₄

HOCH(CH₃)(CH(CH₃)₂) (158.8 mmol, 14 g) in Et₂O (50 mL) was introduced into the flask and cooled to −78° C., and C₄H₉Li/n-hexane, 1.6M (150.4 mmol, 94 mL) was added with stirring. The reaction was warmed to 25° C. and stirred for 18 hours. A slurry of WOCl₄ (35.1 mmol, 12 g) in Et₂O (160 mL) was cooled to −78° C., then the LiOCH(CH₃)(CH(CH₃)₂) solution was added over 1 hour period and 20 mL of Et₂O were added. The mixture was warmed to room temperature and stirred for 2 days. The solvent was removed under vacuum and the resulting liquid was taken in 100 mL of toluene. Filtration at room temperature through Celite® brand diatomaceous earth was performed to remove LiCl salt. Solvent was removed under vacuum and a purification step by distillation was done (103-106° C. at 90 mTorr).

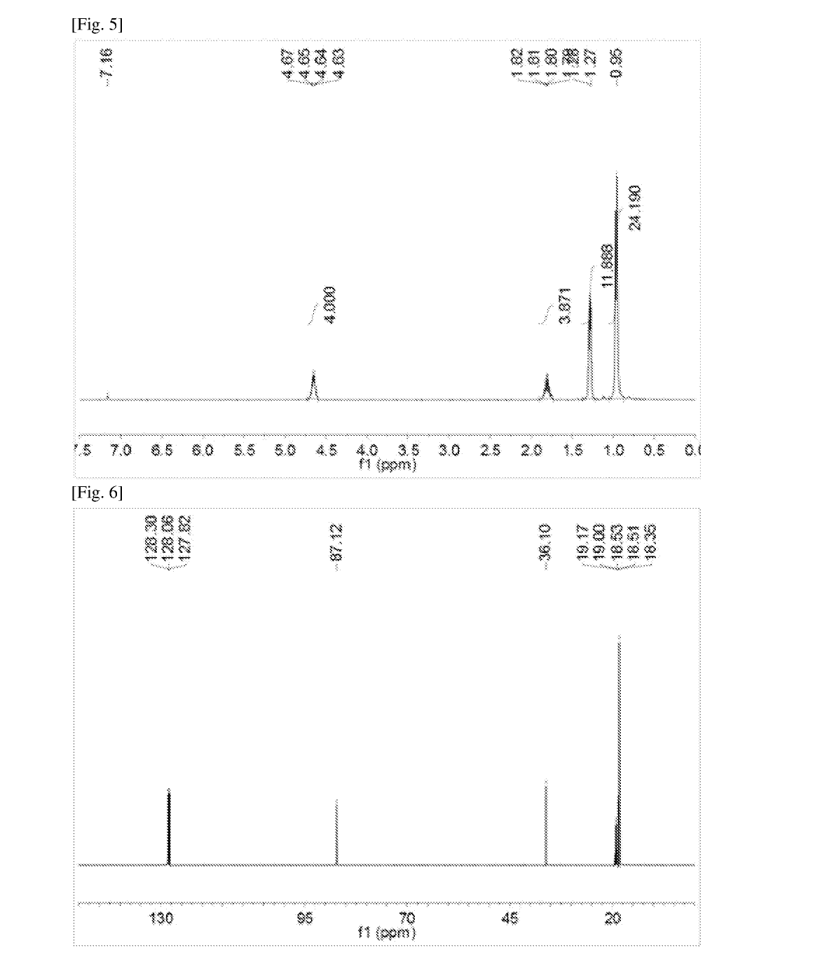

Analysis of the Compound:
The ¹H-NMR spectrum is provided in FIG. 5.

Measurement Condition:
Unit: Jeol (400 MHz)
Solvent: C₆D₆
Method: 1D

δ_{H}: 4.65 (m, OCH(CH₃)CH(CH₃)₂)₄, 4H), 1.80 (m, OCH(CH₃)CH(CH₃)₂)₄, 4H), 1.28 (m, OCH(CH₃)CH(CH₃)₂)₄, 12H), 0.95 (dd, OCH(CH₃)CH(CH₃)₂)₄, 24H, J=7 Hz, J=2.5 Hz)
The ¹³C NMR spectrum is provided in FIG. 6.

Measurement Condition:
Unit: Jeol (400 MHz)
Solvent: C₆D₆
Method: 1D

δ_{C}: (s, 87.12), (s, 36.10), (q, 19.11), (d, 18.52), (s, 18.35)
Vapor pressure: 1 Torr at 147° C.
Pale green liquid and its boiling point is 211° C.
The TG-DTA graph is provided in FIG. 7.

Measurement Conditions:
Sample weight: 24.57 mg
Atmosphere: Nitrogen, 1 atmospheric pressure
Heating rate: 10° C.·min⁻¹
   Solubility of the compound in common solvents

W(═O)(OCH(CH₃)(CH(CH₃)₂))₄ is miscible with common organic solvents such as hexane, acetone, chloroform, and/or toluene.

### Synthesis Example 3: W(═O)(OC(CH₃)₂(C₂H₅))₄

HOC(CH₃)₂(C₂H₅) (3.278 mol, 243 g) in Et₂O (1000 mL) was introduced into the flask and cooled to −78° C., and C₄H₉Li/n-hexane, 1.55M (3.1 mol, 2000 mL) was added with stirring. The reaction was warmed to 25° C. About 1500 mL of solvent was evaporated and the mixture concentrated was stirred for 18 hours. A slurry of WOCl₄ (0.705 mol, 241 g) in Et₂O (1500 mL) was cooled to −78° C., then the LiOC(CH₃)₂(C₂H₅) solution was added over 5 hours period and 50 mL of Et₂O were added. The mixture was warmed to room temperature and stirred for 3 days. The solvent was removed under vacuum and the resulting liquid was taken in n-hexane (2000 mL). Filtration at room temperature through a Celite® brand diatomaceous earth was performed to remove LiCl salt and 50 mL of n-hexane were added. Solvent was removed under vacuum and a purification step by distillation was done. However, pure compound was not isolated since decomposition occurred during the purification step. Applicants believe that decomposition may be avoided with better process conditions.

### Synthesis Example 4: Mo(═O)(OC(CH₃)₃)₄

1 equivalent of Mo(═O)Cl₄ was reacted with 4 equivalents of Li(OtBu) in diethyl ether at −78° C. The mixture was warmed to room temperature (about 25° C.) and stirred. The solvent was removed and the resulting Mo(═O)(OtBu)₄ product was a gold liquid. NMR results are not currently available.

### Synthesis Example 5: Mo(═O)(OCH(Me)(Et))₄

1 equivalent of Mo(═O)Cl₄ was reacted with 4 equivalents of Li(OsBu) in diethyl ether at −78° C. The mixture was warmed to room temperature (about 25° C.) and stirred. The solvent was removed and the resulting Mo(═O)(OtBu)₄ product was a brown oil. However, pure compound was not isolated since decomposition occurred during the purification step. Applicants believe that decomposition may be avoided with better process conditions.

### Comparative Synthesis Example 1: W(═O)(OCH(CH₃)₂)₄

A 300 mL three neck flask equipped with a stirrer was evacuated and replaced therein by nitrogen. A solution of anhydrous isopropanol (48.1 mmol, 2.89 g) in dry toluene (20 mL) and dry tetrahydrofuran (16 mL) was introduced into the flask and cooled to 0° C., and n-butyllithium (1.65 M in hexane, 47.9 mmol, 29.03 mL) was added dropwise with stirring. The reaction was warmed to room temperature and stirred for two hours. A slurry of tungsten(VI) oxytetrachloride (12.0 mmol, 4.09 g) in dry toluene (53 mL) was cooled to 0° C. and the lithium isopropoxide solution was added over a one hour period. The mixture was warmed to room temperature and stirred overnight. Solvent was removed under vacuum and the resulting solid was taken in dry toluene (60 mL) and dry heptane (90 mL) and heated at 80° C. to dissolve the product. Hot filtration at 80° C. through Celite® brand diatomaceous earth was performed in order to remove LiCl salt. Solvent was reduced to 50 mL under vacuum on an oil batch at 40° C., precipitating the product as a white solid. The slurry was filtered, the cake washed with hexane and the solid was dried under vacuum. The resulting white solid was purified by sublimation under a reduced pressure (200 mTorr) at 65° C. As a result of identification as described below, 2.4 g of W(═O)(OiPr)₄ as a white solid were obtained (5.5 mmol, yield=46% based on the tungsten(VI) oxytetrachloride).

It is noteworthy that the yield could not be improved despite several attempts at different scale, the biggest scale (tungsten(VI) oxo tetrachloride (144 mmol, 49.13 g) and LiOⁱPr (1.6 M in hexane, 479 mmol, 294 mL) produced an unidentified brown oil which could not be purified. Therefore, solubility and purification of this compound make its industrial production hard.

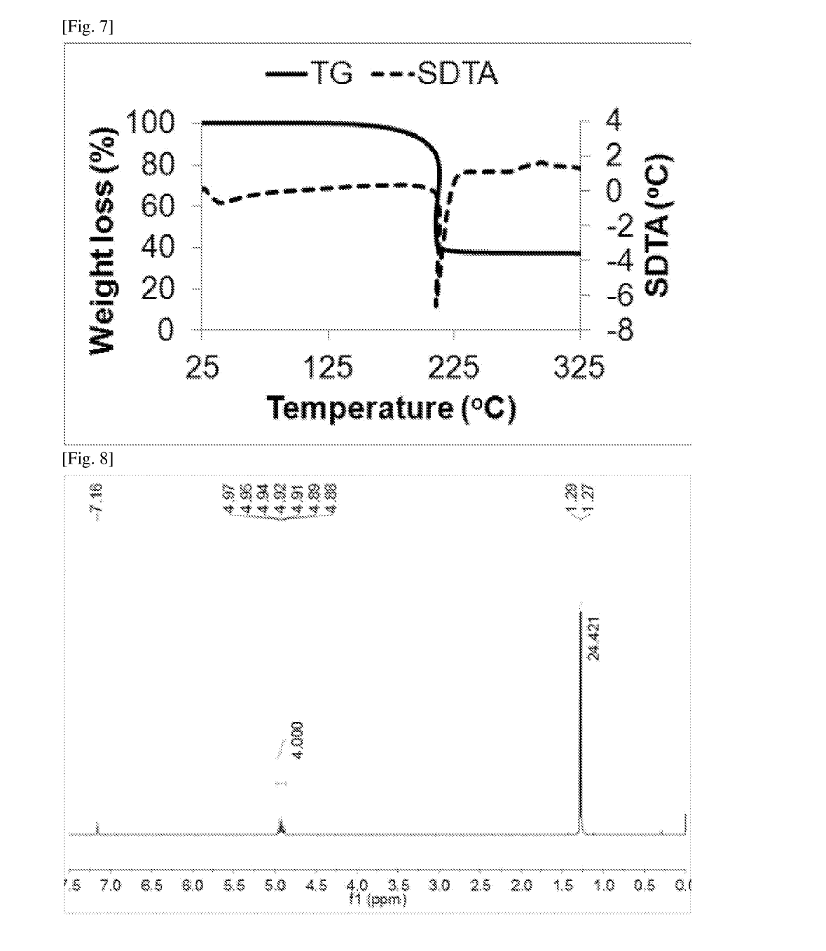

Analysis of the Compound:
The ¹H-NMR spectrum is provided in FIG. 8.

Measurement Condition:
Unit: Jeol (400 MHz)
Solvent: C₆D₆
Method: 1D

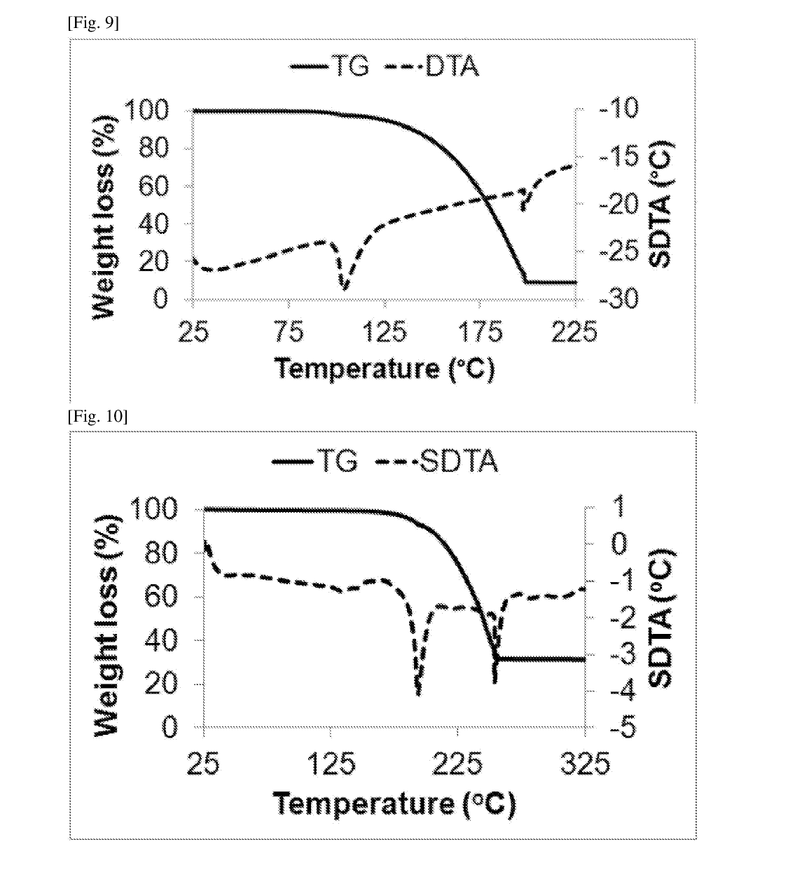

δ_{H}: 4.92 (sept, OCH(CH₃)₂)₄, J=8 Hz, 4H), 1.28 (d, OCH(CH₃)₂)₄, J=8 Hz, 12H)
Vapor pressure: 1 Torr at 103° C.
White solid and its melting point is 103° C.
The TG-DTA graph is provided in FIG. 9.

Measurement Conditions:
Sample weight: 21.19 mg
Atmosphere: Nitrogen, 1 atmospheric pressure
Heating rate: 10° C.·min⁻¹
   Solubility of the compound in common solvents

W(═O)(OiPr)₄ has a very low solubility in alkanes and is soluble in toluene at 60° C.

### Comparative Synthesis Example 2: W(═O)(OnPr)₄

A 100 mL three neck flask equipped with a stirrer was evacuated and replaced therein by nitrogen. A solution of anhydrous n-propanol (48.5 mmol, 2.91 g) in dry toluene (20 mL) and dry tetrahydrofuran (16 mL) was introduced into the flask and cooled to 0° C., and n-butyllithium (1.63 M in hexane, 48.0 mmol, 29.6 mL) was added dropwise with stirring. The reaction was warmed to room temperature and stirred for two hours. A slurry of tungsten(VI) oxytetrachloride (12.0 mmol, 4.01 g) in dry toluene (54 mL) was cooled to 0° C. and the lithium n-propoxide solution was added over a one hour period. The mixture was warmed to room temperature and stirred overnight. Solvent was removed under vacuum on an oil bath at 40° C. and the resulting solid was taken in dry toluene (60 mL) heated at 80° C. to dissolve the product for hot filtration through Celite® brand diatomaceous earth but without success. Solvent was removed under vacuum and sublimation must be done to purify this compound. Due to its very low solubility, no more efforts were conducted on this compound. A part of the solid was taken in toluene and a filtration through micropore filter was performed in order to get enough material without salt to perform TG-DTA analysis.

Analysis of the Compound:
Purification has not yet been performed, so no NMR analysis has occurred.
White solid and its melting point is 193° C.
The TG-DTA graph is provided in FIG. 10.

Measurement Conditions:
Sample weight: 23.09 mg
Atmosphere: Nitrogen, 1 atmospheric pressure
Heating rate: 10° C.·min⁻¹
   Solubility of the compound in common solvents

W(═O)(OnPr)₄ has a very low solubility in alkanes and toluene at room temperature

### Comparative Synthesis Example 3: W(═O)(OCH₂CH(CH₃)₂)₄

A 100 mL three neck flask equipped with a stirrer was evacuated and replaced therein by nitrogen. A solution of anhydrous iso-butanol (24.25 mmol, 1.8 g) in dry toluene (10 mL) and dry tetrahydrofuran (8 mL) was introduced into the flask and cooled to 0° C., and n-butyllithium (1.63 M in hexane, 24 mmol, 14.8 mL) was added dropwise with stirring. The reaction was warmed to room temperature and stirred for two hours. A slurry of tungsten(VI) oxytetrachloride (6 mmol, 2.05 g) in dry toluene (27 mL) was cooled to 0° C. and the lithium iso-butoxide solution was added over a one hour period. The mixture was warmed to room temperature and stirred overnight. Solvent was removed under vacuum on an oil bath at 40° C. and the resulting solid was taken in dry toluene (30 mL) heated at 80° C. to dissolve the product for hot filtration through Celite® brand diatomaceous earth but without success. Solvent was removed under vacuum and sublimation must be done to purify this compound. Due to its very low solubility, no more efforts were conducted on this compound. A part of the solid was taken in toluene and a filtration through micropore filter was performed in order to get enough material without salt to perform TG-DTA analysis.

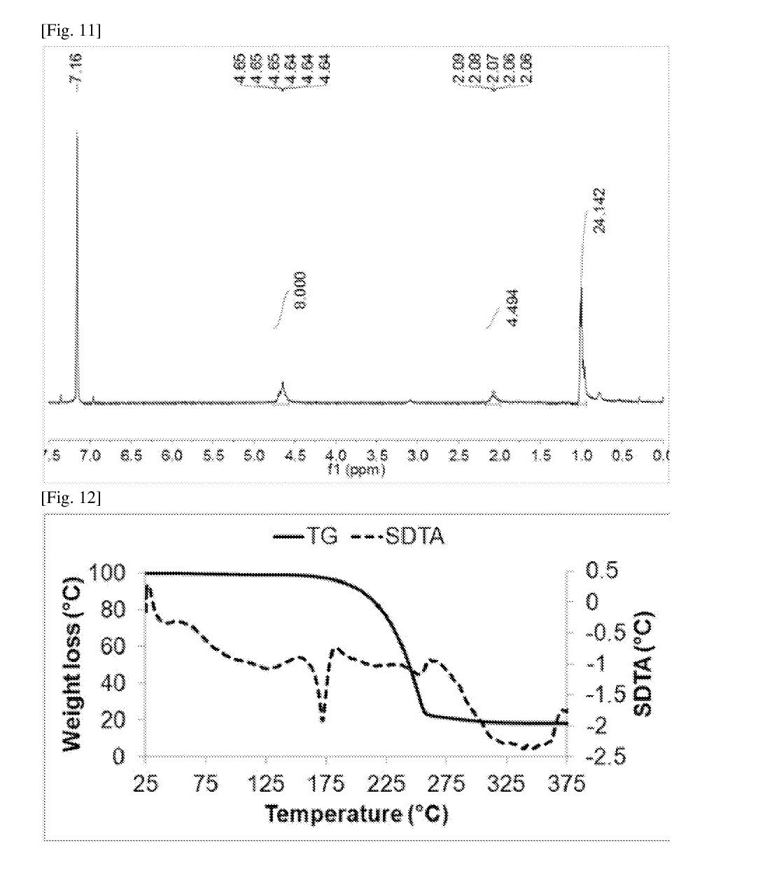

Analysis of the Compound:
The ¹H-NMR spectrum is provided in FIG. 11.

Measurement Condition:
Unit: Jeol (400 MHz)
Solvent: C₆D₆
Method: 1D

δ_{H}: 4.65 (m, OCH₂CH(CH₃)₂)₄, 8H), 2.07 (m, OCH₂CH(CH₃)₂)₄, 4H), 1.01 (d, OCH₂CH(CH₃)₂)₄
White solid and its melting point is 172° C.
The TG-DTA graph is provided in FIG. 12.

Measurement Conditions:
Sample weight: 19.79 mg
Atmosphere: Nitrogen, 1 atmospheric pressure
Heating rate: 10° C.·min⁻¹
   Solubility of the compound in common solvents

W(═O)(OiBu)₄ has a very low solubility in alkanes and in toluene up to 80° C.

### Comparative Synthesis Example 4: W(═O)(OnBu)₄

A 100 mL three neck flask equipped with a stirrer was evacuated and replaced therein by nitrogen. Anhydrous n-butanol (130 mmol, 9.72 g) was introduced into the flask and cooled to 0° C., and sodium metal (11.7 mmol, 268 mg) was added with stirring. The reaction was warmed to room temperature and stirred for two hours. A slurry of tungsten(VI) oxytetrachloride (2.9 mmol, 1.0 g) in dry diethyl ether (12 mL) was cooled to 0° C., the sodium n-butoxide solution was added over a one hour period and 12 mL of n-butanol were added. The mixture was warmed to room temperature and heated to 35° C. for 30 min. Solvent was removed under vacuum and the resulting white solid was taken in dry toluene (30 mL). Filtration at room temperature through a micropore filter (45 m) was performed to remove NaCl salt. Solvent was removed under vacuum. and a purification step by sublimation must be done.

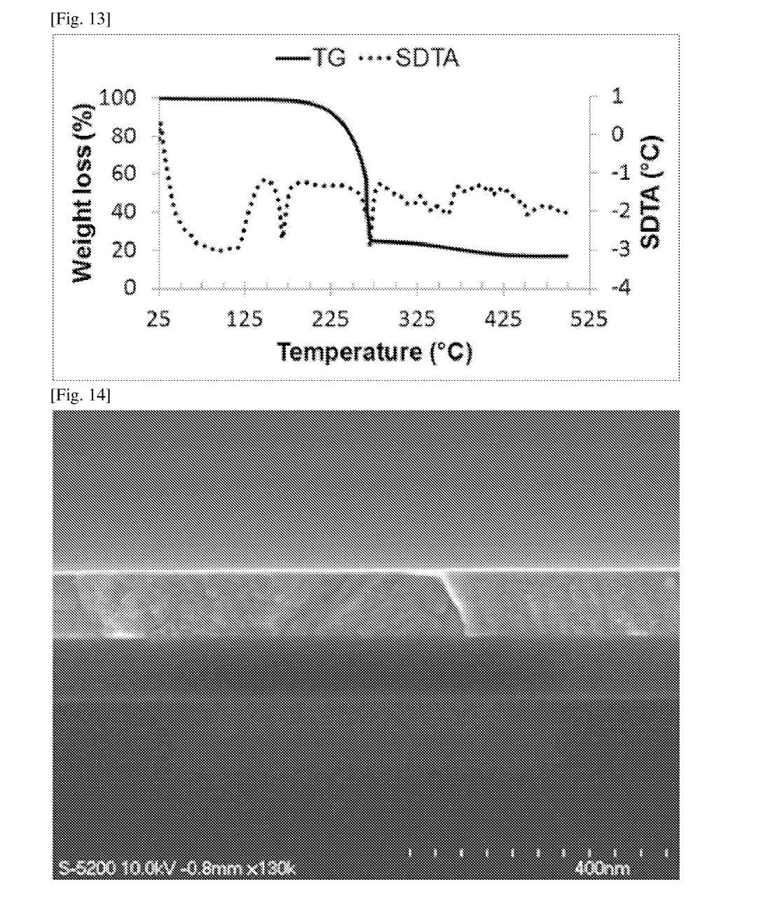

Analysis of the Compound:
Purification has not yet been performed, so no NMR analysis has occurred.
White solid and its melting point is 168° C.
The TG-DTA graph is provided in FIG. 13.

Measurement Conditions:
Sample weight: 27.43 mg
Atmosphere: Nitrogen, 1 atmospheric pressure
Heating rate: 10° C.·min⁻¹
   Solubility of the compound in common solvents

W(═O)(OnBu)₄ has a very low solubility in alkanes and toluene at room temperature.

### Example 1: Dip-Coating of Tungsten Oxide from W(═O)(OsBu)₄

A solution composed of the W(═O)(OsBu)₄ material as synthesized in Synthesis Example 1, hydrogen peroxide solution (30%) and ethanol in mass ratio of 1:0.13:1.01, respectively, was prepared previous to dip coating. The resulting solution was filtered through a 0.45 μm pore filter and the mixture is allowed to sit at room temperature for 16 h.

A silicon substrate was thoroughly cleaned with isopropanol and dried before the deposition. The substrate was then dipped into the solution and pulled up at a controlled rate at 0.5 mm/sec for both dipping and withdrawing speeds. The layer applied on the substrate was dried at room temperature for 10 minutes to vaporize the solvent. The tungsten layer on the substrates was then decomposed at 550° C. for 20 minutes.

The Scanning Electron Microscopy (SEM) image of the resulting film, see FIG. 14, shows that the film is uniform. An X-ray Photoelectron spectroscopy analysis of the film exhibited the composition of tungsten oxide, with no evidence of carbon in the film. Hydrogen is not detectable by XPS, thus the possibility of hydroxide is not negligible. At the signal range corresponding to tungsten compounds shows two distinct pairs of signals corresponding to two different states of tungsten. Formation of multiple tungsten oxidation states can be avoided with process optimization.

### Example 2: Dip-Coating of Tungsten Oxide from W(═O)(OCH(Me)(iPr))₄

A solution composed of the W(═O)(OCH(Me)(iPr))₄ material synthesized in Synthesis Example 2, hydrogen peroxide solution (30%) and ethanol in mass ratio of 1:0.11:1.01, respectively, was prepared previous to dip coating. The resulting solution was filtered through a 0.45 m pore filter and the mixture is allowed to sit at room temperature for 16 h.

A silicon substrate to be deposited was thoroughly cleaned with isopropanol and dried before the deposition. The substrate was then dipped into the solution and pulled up at a controlled rate at 0.5 mm/sec for both dipping and withdrawing speeds. The layer applied on the substrate was dried at room temperature for 10 minutes to vaporize the solvent. The tungsten layer on the substrates was then decomposed at 550° C. for 20 minutes. Dip-coating, drying and annealing steps were performed 2 times in order to get a significant layer.

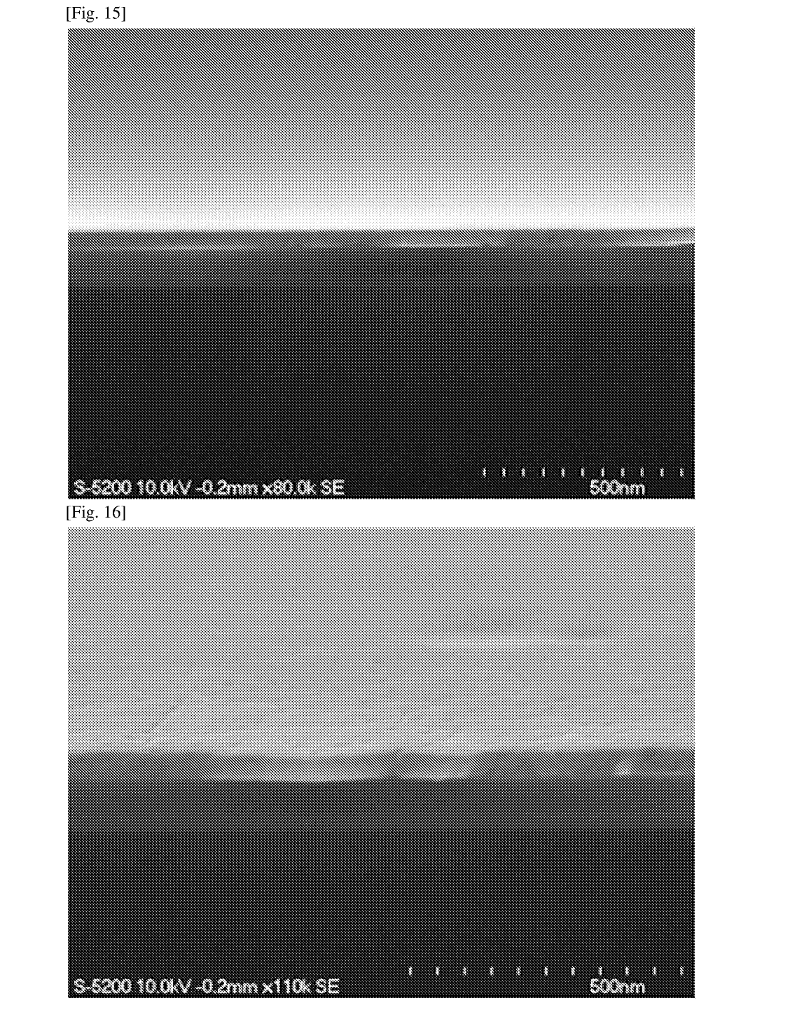

FIG. 15, is a Scanning Electron Microscope (SEM) picture showing a cross-sectional view of the resulting film at magnification of ×80,000. FIG. 16 is a SEM picture showing a surface view of the resulting film at a magnification of ×110,000. As can be seen in FIG. 16, the film is uniform. An X-ray Photoelectron spectroscopy analysis of the film exhibited the composition of tungsten oxide, with no evidence of carbon in the film. Hydrogen is not detectable by XPS, thus the possibility of hydroxide is not negligible. At the signal range corresponding to tungsten compounds shows two distinct pairs of signals corresponding to two different states of tungsten. Formation of multiple tungsten oxidation states can be avoided with process optimization.

### Comparative Example 1: Dip-Coating of Tungsten Oxide from W(═O)(OnPr)₄

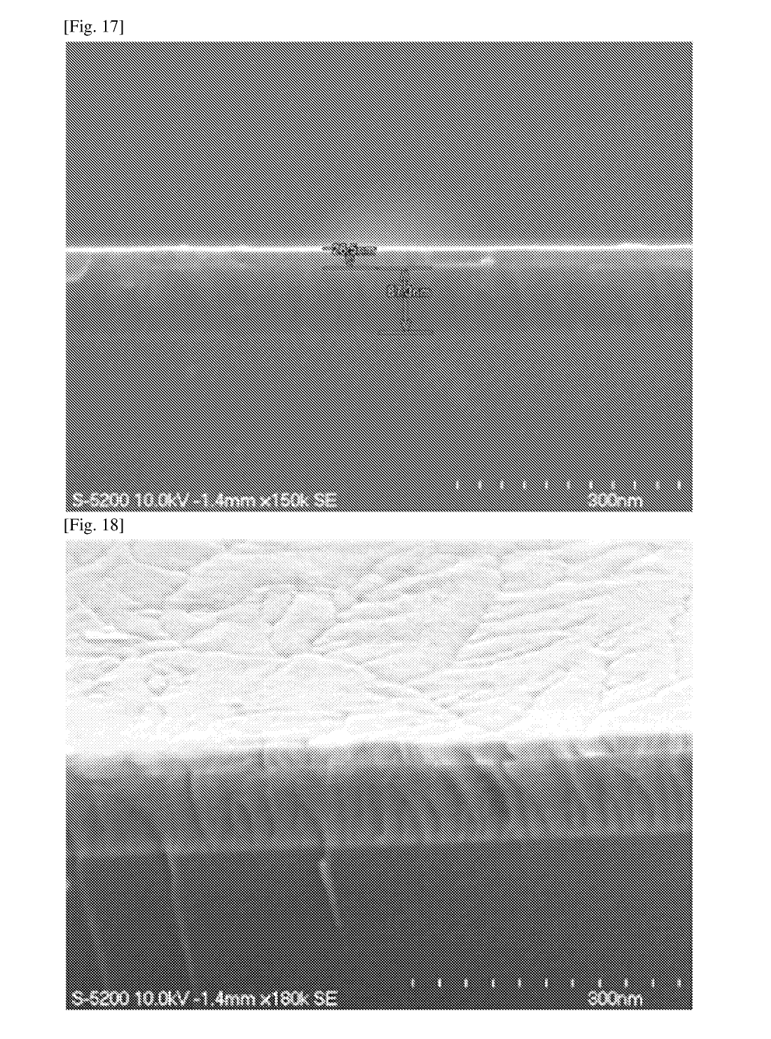

A solution composed of the W(═O)(OnPr)₄ material synthesized in Comparative Synthesis Example 2, hydrogen peroxide solution (30%) and ethanol in mass ratio of 1:1.9:50, respectively, was prepared previous to dip coating. The resulting solution was filtered through a 0.45 m pore filter and the mixture is allowed to sit at room temperature for 16 h. A silicon substrate to be deposited was thoroughly cleaned with isopropanol and dried before the deposition. The substrate was then dipped into the solution and pulled up at a controlled rate at 0.5 mm/sec for both dipping and withdrawing speeds. The layer applied on the substrate was dried at room temperature for 10 minutes to vaporize the solvent. The tungsten layer on the substrates was then decomposed at 550° C. for 20 minutes. Dip-coating, drying and annealing steps were performed 4 times in order to get a significant layer. FIG. 17 is a Scanning Electron Microscope (SEM) picture showing a cross-sectional view of the resulting film at magnification of ×150,000. FIG. 18 is a SEM picture showing a surface view of the resulting film at magnification of ×180,000. As can be seen in FIG. 17, a 26.5 nm layer was deposited on a 87.3 nm substrate. As can be seen in FIG. 18, the film is uniform. An X-ray Photoelectron spectroscopy analysis of the film exhibited the composition of tungsten oxide, with no evidence of carbon in the film. Hydrogen is not detectable by XPS, thus the possibility of hydroxide is not negligible. At the signal range corresponding to tungsten compounds shows two distinct pairs of signals corresponding to two different states of tungsten. Formation of multiple tungsten oxidation states can be avoided with process optimization.

### Comparative Example 2: Dip-Coating of Tungsten Oxide from W(═O)(OiBu)₄

A solution composed of the W(═O)(OiBu)₄ material synthesized in Comparative Synthesis Example 3, hydrogen peroxide solution (30%) and ethanol in mass ratio of 1:6.9:36, respectively, was prepared previous to dip coating. The resulting solution was filtered through a 0.45 m pore filter and the mixture is allowed to sit at room temperature for 16 h. A silicon substrate to be deposited was thoroughly cleaned with isopropanol and dried before the deposition. The substrate was then dipped into the solution and pulled up at a controlled rate at 0.5 mm/sec for both dipping and withdrawing speeds. The layer applied on the substrate was dried at room temperature for 10 minutes to vaporize the solvent. The tungsten layer on the substrates was then decomposed at 550° C. for 20 minutes. Dip-coating, drying and annealing steps were performed 2 times in order to get a significant layer.

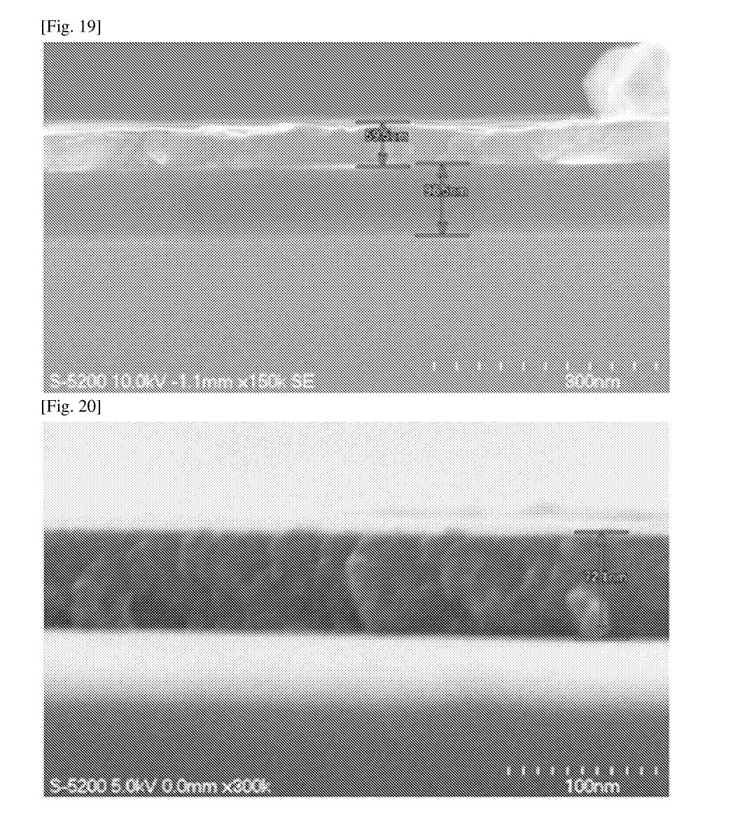

The Scanning Electron Microscopy image of the resulting film, see FIG. 19, shows a cross sectional view at magnification ×150,000. As can be seen in FIG. 19, a 59.5 nm layer was deposited on a 96.5 nm substrate and the cross-section appears uniform. An X-ray Photoelectron spectroscopy analysis of the film exhibited the composition of tungsten oxide, with no evidence of carbon in the film. Hydrogen is not detectable by XPS, thus the possibility of hydroxide is not negligible. At the signal range corresponding to tungsten compounds shows two distinct pairs of signals corresponding to two different states of tungsten. Formation of multiple tungsten oxidation states can be avoided with process optimization.

### Example 3: Chemical Vapor Deposition of WO₃ from W(═O)(OsBu)₄

A typical CVD system, shown in FIG. 1, was used to perform CVD deposition of a tungsten oxide film. The W(═O)(OsBu)₄ source was stored in a stainless canister maintained at 60° C. The precursor was controlled to have a constant flow of 0.3 sccm using 30 sccm of Argon carrier gas, resulting in about 40 Torr of canister pressure. The downstream supply line of the canister was wrapped with heating tapes to maintain a constant temperature of 75° C. 50 sccm of oxygen gas was co-fed into the reactor. The pressure and temperature of the reactor were kept at 20 Torr and room temperature, respectively, and the deposition was done for 60 minutes on a silicon substrate.

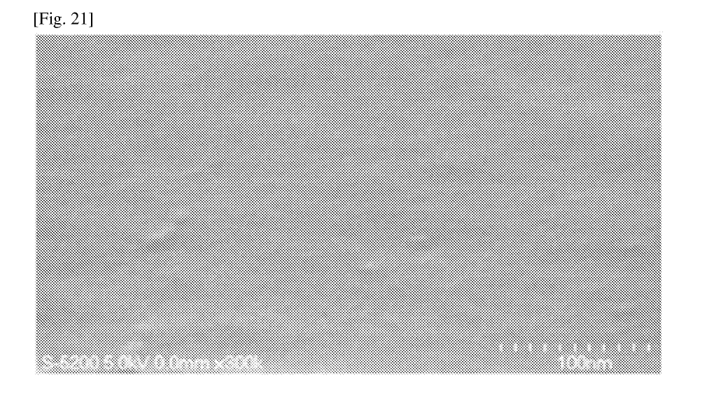

The Scanning Electron Microscopy image of the resulting film, see FIG. 20, showing a cross sectional view at magnification ×300,000, and FIG. 21, showing a surface view at magnification ×300,000, showed that the film is uniform. As seen in FIG. 20, a 72.1 nm layer was deposited. An X-ray Photoelectron spectroscopy analysis of the film exhibited the composition of tungsten oxide, with no evidence of carbon-containing tungsten film. Hydrogen is not detectable by XPS, thus the possibility of hydroxide is not negligible. At the signal range corresponding to tungsten compounds shows two distinct pairs of signals corresponding to two different states of tungsten. Formation of multiple tungsten oxidation states can be avoided with process optimization.

As described in the Background, prior chemical vapor deposition processes using tungsten precursors required higher temperatures. Cf. Baxter et al., Chem. Commun. 1996 pp. 1129-1130 (performing CVD with W(═O)(OR)₄, with R=Et, iPr, tBu or CH₂tBu, at 120° C. or higher) and M. Basato et al., Chemical Vapor Deposition, 2001, 7(5), 219-224) (performing CVD with W(═O)(OtBu)₄ and H₂O at 100-150° C.).

Depositions at lower temperatures using the disclosed precursors are beneficial because energy load may be reduced during the deposition. One of ordinary skill in the art will recognize that CVD depositions using the W(═O)(OsBu)₄ precursor may be performed at higher temperatures, provided that they are performed at less than the decomposition temperature of the precursor.

### INDUSTRIAL APPLICABILITY

The liquid W(═O)(OsBu)₄ tungsten oxo sec-butoxide of the present invention has a vapor pressure of 1 Torr at 123° C., about one order of magnitude higher than the solid compound such as W(═O)(OiPr)₄ at the same temperature. Accordingly, the present liquid compound can be purified by distillation more effectively in large scale. It can supply a large amount of vapor easily in mass-production scale CVD. It can be used for preparing solution or sol-gel for deposition by spray, dip-coating, slit coating or related deposition techniques.

It will be understood that many additional changes in the details, materials, steps, and arrangement of parts, which have been herein described and illustrated in order to explain the nature of the invention, may be made by those skilled in the art within the principle and scope of the invention as expressed in the appended claims. Thus, the present invention is not intended to be limited to the specific embodiments in the examples given above and/or the attached drawings.

1. A group 6 film forming composition comprising a liquid precursor having the formula M(═O)(OR)₄, wherein M is Mo or W and each R is independently selected from the group consisting of tBu, sBu, CH₂sBu, CH₂iBu, CH(Me)(iPr), CH(Me)(nPr), CH(Et)₂, C(Me)₂(Et), a C6-C8 alkyl group, and combinations thereof, provided that every R is tBu only when M is Mo.

2. The Group 6 film forming composition of claim 1, wherein the liquid precursor is Mo(═O)(OtBu)₄.

3. The Group 6 film forming composition of claim 1, wherein the liquid precursor is W(═O)(OsBu)₄.

4. The Group 6 film forming composition of claim 1, wherein the liquid precursor has the formula W(═O)(OCH₂R)₄, wherein each R is independently sBu or iBu.

5. The Group 6 film forming composition of claim 1, wherein the liquid precursor is selected from the group consisting of W(═O)(OCH(Me)(iPr))₄, W(═O)(OCH(Me)(nPr))₄, and W(═O)(OCH(Et)₂)₄.

6. The Group 6 film forming composition of claim 1, wherein the liquid precursor is W(═O)(OC(Me)₂(Et))₄.

7. The Group 6 film forming composition of claim 1, wherein the liquid precursor has the formula W(═O)(OR)₄, wherein at least one R is a C6-C8 alkyl chain.

8. The Group 6 film forming composition of claim 1, the composition comprising between approximately 0 atomic % and 5 atomic % of M(OR)₆.

9. The Group 6 film forming composition of claim 1, the composition comprising between approximately 0 ppmw and 200 ppm of Cl.

10. The Group 6 film forming composition of claim 1, further comprising a solvent.

11. The Group 6 film forming composition of claim 10, wherein the solvent is selected from the group consisting of C1-C16 hydrocarbons, THF, DMO, ether, pyridine, and combinations thereof.

12. A method of forming a Group 6-containing film on a substrate, the method comprising forming a solution comprising the Group 6 film forming composition of claim 1; and contacting the solution with the substrate via a spin coating, spray coating, dip coating, or slit coating technique to form the Group 6-containing film.

13. A method of forming a Group 6-containing film on a substrate, the method comprising introducing into a reactor having the substrate therein a vapor of the Group 6 film forming composition of claim 1; and depositing at least part of the precursor onto the substrate to form the Group 6-containing film.

14. The method of claim 13, further comprising introducing a reactant into the reactor, the reactant being selected from the group consisting of O₂, O₃, H₂O, H₂O₂, NO, N₂O, NO₂, oxygen radicals thereof, and mixtures thereof.

15. The method of claim 12, wherein the liquid precursor is Mo(═O)(OtBu)₄.

16. The method of claim 12, wherein the liquid precursor is W(═O)(OsBu)₄.

17. The method of claim 12, wherein the liquid precursor has the formula W(═O)(OCH₂R)₄, wherein each R is independently sBu or iBu.

18. The method of claim 13, wherein the liquid precursor is Mo(═O)(OtBu)₄.

19. The method of claim 13, wherein the liquid precursor is W(═O)(OsBu)₄.

20. The method of claim 13, wherein the liquid precursor has the formula W(═O)(OCH₂R)₄, wherein each R is independently sBu or iBu.
